(19) United States
(12) Patent Application Publication
(10) Pub. No.: US 2012/0264299 A1
(43) Pub. Date: Oct. 18, 2012

(54) CHEMICAL MECHANICAL POLISHING METHOD

(75) Inventors: Chien-Mao Liao, Taipei County (TW); Yi-Nan Chen, Taipei City (TW); Hsien-Wen Liu, Taoyuan County (TW)

(73) Assignee: NANYA TECHNOLOGY CORPORATION, Taoyuan (TW)

(21) Appl. No.: 13/085,487

(22) Filed: Apr. 13, 2011

(51) Int. Cl. H01L 21/306

(52) U.S. Cl. 438/692; 257/E21.23

(57) ABSTRACT

A chemical mechanical polishing (CMP) method is provided The method is capable of polishing a substrate in a CMP apparatus by using a hydrophobic polishing pad and includes following steps. A first CMP process is performed to the substrate. A first cleaning process is performed to the hydrophobic polishing pad. A second CMP process is performed to the substrate, wherein the first CMP process, the first cleaning process and the second CMP process are performed in sequence.

### BACKGROUND OF THE INVENTION

1. Field of the Invention

The invention is related to a chemical mechanical polishing method and more particularly to a segmented chemical mechanical polishing method.

2. Description of Related Art

Because the resolution of photolithography exposure increases along with the decrease in device size and the depth of field at exposure is reduced, the requirement to evenness of chip surface increases drastically. Thus, when performing the deep sub-micron process, the planarization of the chip then depends on the chemical mechanical polishing (CMP) process. The unique anisotropic polishing property of the CMP process is not only used for the planarization of the surface contour of the chip, but can also be applied in the fabrication of damascene structures of perpendicular and horizontal metal interconnections, the fabrication of shallow trench isolations in devices and the fabrication of advanced devices in the previous stage, and the fabrication of micro-electromechanical system planarization and the fabrication of flat displays, etc.

The CMP process mainly utilizes a reagent in the polishing slurry for generating a chemical reaction on the front side of the wafer to form a polishable layer. Further, with the wafer on the polishing pad, the protruding portions of the polishable layer are polished off by the mechanical polishing with the facilitation of abrasive particles in the polishing slurry. The chemical reactions and the mechanical polishing are then repeated to form a planar surface.

However, when the CMP process is performed to the substrate using the hydrophobic polishing pad, byproducts such as surfactants and so on are accumulated on the hydrophobic polishing pad, so that the polishing rate is reduced.

### SUMMARY OF THE INVENTION

The invention is directed to a chemical mechanical polishing (CMP) method capable of enhancing a polishing efficiency when using a hydrophobic polishing pad.

The invention is directed to a CMP method capable of polishing a substrate in a CMP apparatus by using a hydrophobic polishing pad. The CMP method includes the following steps. A first CMP process is performed to the substrate. A first cleaning process is then performed to the hydrophobic polishing pad. Afterwards, a second CMP process is performed to the substrate, wherein the first CMP process, the first cleaning process and the second CMP process are performed in sequence.

According to an embodiment of the invention, in the CMP method, the first cleaning process is a brush cleaning process or a diamond dressing process, for example.

According to an embodiment of the invention, in the CMP method, the substrate is further removed from the hydrophobic polishing pad after the first CMP process is performed and before the first cleaning process is performed.

According to an embodiment of the invention, in the CMP method, the substrate is further removed from the CMP apparatus after the second CMP process is performed.

According to an embodiment of the invention, in the CMP method, a second cleaning process is further performed to the hydrophobic polishing pad after the second CMP process is performed.

According to an embodiment of the invention, in the CMP method, the second cleaning process is a diamond dressing process, for example.

According to an embodiment of the invention, in the CMP method, the first CMP process, the first cleaning process, and the second CMP process are performed in-situ, for instance.

According to an embodiment of the invention, in the chemical mechanical method, an operation time of the first CMP process is less than 120 seconds, for instance.

According to an embodiment of the invention, in the chemical mechanical method, an operation time of the first cleaning process is less than 60 seconds, for example.

According to an embodiment of the invention, in the chemical mechanical method, an operation time of the second CMP process is less than 120 seconds, for instance.

In light of the foregoing, in the CMP method provided in the invention, the first cleaning process is performed to the hydrophobic polishing pad between the first polishing process and the second polishing process to remove byproducts such as surfactants and the like accumulated on the hydrophobic polishing pad. As a consequence, the polishing efficiency of the hydrophobic polishing pad is enhanced, thereby increasing the polishing rate of the substrate.

In order to make the aforementioned and other features of the invention more comprehensible, several embodiments accompanied with figures are described in detail below.

### BRIEF DESCRIPTION OF THE DRAWINGS

The accompanying drawings are included to provide further understanding, and are incorporated in and constitute a part of this specification. The drawings illustrate embodiments and, together with the description, serve to explain the principles of the invention.

FIG. 1 illustrates a flowchart of a chemical mechanical polishing method according to an embodiment of the invention.

### DESCRIPTION OF EMBODIMENTS

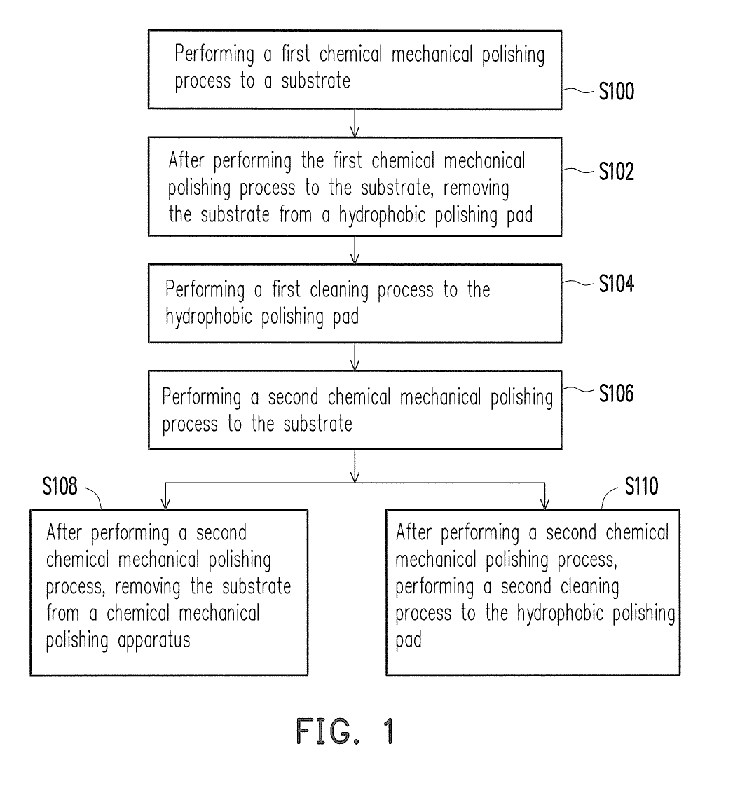

FIG. 1 illustrates a flowchart of a chemical mechanical polishing (CMP) method according to an embodiment of the invention.

The CMP method disclosed in the present embodiment is illustrated by polishing a substrate in a CMP apparatus by using a hydrophobic polishing pad. Here, the substrate is a silicon wafer, for example, but is not limited thereto.

Firstly, in step S100, a first CMP process is performed to a substrate. That is, the substrate is placed into a CMP apparatus and polished using a hydrophobic polishing pad to remove a portion of the substrate. An operation time of the first CMP process is, for instance, less than 120 seconds.

Next, step S102 is optionally performed to remove the substrate from the hydrophobic polishing pad after the first CMP process is performed to the substrate. A first cleaning process subsequently performed to the hydrophobic polishing pad thus becomes more convenient.

In step S104, the first cleaning process is then performed to the hydrophobic polishing pad. The first cleaning process is, for example, a brush cleaning process or a diamond dressing process. Herein, when the first cleaning process is a brush cleaning process, for example, the lifespan of the hydrophobic polishing pad is therefore extended. An operation time of the first cleaning process is, for instance, less than 60 seconds.

Later, in step S106, a second CMP process is performed to the substrate. That is, the substrate is placed on the hydrophobic polishing pad again for polishing the substrate to a target thickness. At this time, the hydrophobic polishing pad has superior polishing efficiency as the hydrophobic polishing pad is already cleaned by the first cleaning process. An operation time of the second CMP process is, for instance, less than 120 seconds. It should be noted that steps S100, S104, and S106 are performed in-situ, for instance. In other words, these steps are performed in the same CMP apparatus, so that the fabrication time can be reduced effectively.

Additionally, step S108 is performed optionally to remove the substrate from the CMP apparatus after the second CMP process is performed to complete the polishing of the substrate.

Furthermore, step S110 is performed optionally, where a second cleaning process is performed to the hydrophobic polishing pad after the second CMP process is performed to remove the byproducts resided on the hydrophobic polishing pad and trenches thereof. Therefore, the next substrate can then be polished effectively. The second cleaning process is, for example, a diamond dressing process. An operation time of the second cleaning process is, for instance, less than 60 seconds. In the embodiment, step S108 is performed with step S110 simultaneously, but the invention is not limited thereto.

As shown from the above embodiment, after the first polishing process is performed to the substrate, byproducts such as surfactants and so on are accumulated on the hydrophobic polishing pad so as to reduce the polishing efficiency of the hydrophobic polishing pad. Therefore, after the first polishing process is performed to the substrate, the first cleaning process is performed to the hydrophobic polishing pad to remove the byproducts accumulated on the hydrophobic polishing pad, such that the polishing efficiency of the hydrophobic polishing pad can be enhanced. The second polishing process is performed to the substrate through the hydrophobic polishing pad cleaned after the first cleaning process, such that the polishing rate of the substrate is increased. Accordingly, the segmented CMP method of the embodiment has a faster polishing rate and the overall polishing time can be reduced.

In summary, the embodiment includes at least the following features:

1. The CMP method of the embodiment enhances the polishing efficiency of the hydrophobic polishing pad.

2. The polishing rate is increased and the overall polishing time is shortened through the CMP method of the embodiment.

It will be apparent to those skilled in the art that various modifications and variations can be made to the structure of the disclosed embodiments without departing from the scope or spirit of the invention. In view of the foregoing, it is intended that the invention cover modifications and variations of this invention provided they fall within the scope of the following claims and their equivalents.

What is claimed is:

1. A chemical mechanical polishing method, capable of polishing a substrate in a chemical mechanical polishing apparatus by using a hydrophobic polishing pad, and the chemical mechanical polishing method comprising:
performing a first chemical mechanical polishing process to the substrate;
performing a first cleaning process to the hydrophobic polishing pad; and
performing a second chemical mechanical polishing process to the substrate, wherein the first chemical mechanical polishing process, the first cleaning process and the second chemical mechanical polishing process are performed in sequence.

2. The chemical mechanical polishing method as claimed in claim 1, wherein the first cleaning process comprises a brush cleaning process or a diamond dressing process.

3. The chemical mechanical polishing method as claimed in claim 1, wherein after the first chemical mechanical polishing process is performed and before the first cleaning process is performed, the substrate is further removed from the hydrophobic polishing pad.

4. The chemical mechanical polishing method as claimed in claim 1, wherein after the second chemical mechanical polishing process is performed, the substrate is further removed from the chemical mechanical polishing apparatus.

5. The chemical mechanical polishing method as claimed in claim 1, wherein after the second chemical mechanical polishing process is performed, a second cleaning process is further performed to the hydrophobic polishing pad.

6. The chemical mechanical polishing method as claimed in claim 5, wherein the second cleaning process comprises a diamond dressing process.

7. The chemical mechanical polishing method as claimed in claim 1, wherein the first chemical mechanical polishing process, the first cleaning process, and the second chemical mechanical polishing process are performed in-situ.

8. The chemical mechanical polishing method as claimed in claim 1, wherein an operation time of the first chemical mechanical polishing process is less than 120 seconds.

9. The chemical mechanical polishing method as claimed in claim 1, wherein an operation time of the first cleaning process is less than 60 seconds.

10. The chemical mechanical polishing method as claimed in claim 1, wherein an operation time of the second chemical mechanical polishing process is less than 120 seconds.
